(19) United States
(12) Patent Application Publication
(10) Pub. No.: US 2025/0307519 A1
(43) Pub. Date: Oct. 2, 2025

(54) 3D STACKED SEMICONDUCTOR DEVICE WITH INTEGRATED FOLDED DATA PATH FOR ENHANCED WIRE DELAY OPTIMIZATION

(71) Applicant: Advanced Micro Devices, Inc., Santa Clara, CA (US)

(72) Inventors: Spence Oliver, Austin, TX (US); Matthew Pickett, Fort Collins, CO (US)

(73) Assignee: Advanced Micro Devices, Inc., Santa Clara, CA (US)

(21) Appl. No.: 18/620,910

(22) Filed: Mar. 28, 2024

(51) Int. Cl. G06F 30/3947; G06F 30/327; G06F 30/337

(52) U.S. Cl. CPC G06F 30/3947; G06F 30/327; G06F 30/337

(57) ABSTRACT

Apparatuses, systems, and methods relating to three-dimensional stacked semiconductor devices with integrated folded data paths for enhanced wire delay optimization are described. In one example, a semiconductor device includes a first die and a second die. The first die can include a data source, and the second die can include an execution unit. The second die is oriented in a common plane with the first die and positioned relative to the first die in a vertical dimension perpendicular to an orientation of the common plane. The semiconductor device can also include a data path that electrically couples the data source and the execution unit. Various additional apparatuses, systems, and methods are disclosed.

### BACKGROUND

In recent years, the semiconductor industry has seen significant developments in the architecture and design of processors, driven by the ever-increasing demand for higher performance, efficiency, and miniaturization. As processors have become more complex, integrating a larger number of functional units and data storage elements, challenges have emerged in maintaining efficient data paths within these devices. One such challenge is the management of wire delay, which is the time taken for signals to travel between different components of a processor. As the physical distances within processors increase due to the addition of more components, wire delays can significantly impact the overall speed and efficiency of the processor.

Additionally, the physical footprint of processors presents limitations due to space constraints. This can hinder the addition of more functional units or storage elements, posing a significant challenge in the design and manufacture of compact yet powerful semiconductor devices. The need to optimize the arrangement of components within a processor to minimize wire delay, while also addressing the challenges of physical space constraints, has become a critical aspect of semiconductor device design.

### BRIEF DESCRIPTION OF THE DRAWINGS

The accompanying drawings illustrate a number of example implementations and are a part of the specification. Together with the following description, these drawings demonstrate and explain various principles of the instant disclosure.

FIG. 1 depicts a block diagram of a processing system in accordance with some implementations, examples, and/or variations of the apparatuses, systems, and methods described herein.

FIG. 2 shows a block diagram of an example physical processor in accordance with some implementations, examples, and/or variations of the apparatuses, systems, and methods described herein.

FIG. 3 presents a top view of an example processor core that includes a data source, an execution unit, and a data path in accordance with some variations, examples, and/or implementations described herein.

FIG. 4 shows a cross-section view of a portion of an example processor core that can include a data source, an execution unit, and a data path in accordance with some variations, examples, and/or implementations described herein.

FIG. 5 shows a cross-section view of a data source, execution unit, and data path included on different layers or dies within a silicon stack in accordance with some variations, examples, and/or implementations described herein.

FIG. 6 shows a top view of an example implementation of a processor core that includes a data source, a plurality of execution units, and a plurality of data paths in accordance with some variations, examples, and/or implementations described herein.

FIG. 7, FIG. 8, and FIG. 9 show different example configurations of data sources and execution units in accordance with some variations, examples, and/or implementations described herein.

FIG. 10 is a flow diagram of an example method for creating a stacked semiconductor device with integrated folded data paths in accordance with some variations, examples, and/or implementations described herein.

Throughout the drawings, identical reference characters and descriptions indicate similar, but not necessarily identical, elements. While the example implementations described herein are susceptible to various modifications and alternative forms, specific embodiments have been shown by way of example in the drawings and will be described in detail herein. However, the example implementations described herein are not intended to be limited to the particular forms disclosed. Rather, the instant disclosure covers all modifications, equivalents, and alternatives falling within the scope of the appended claims.

### DETAILED DESCRIPTION OF EXAMPLE IMPLEMENTATIONS

The present disclosure describes various apparatuses, systems, and methods related to three-dimensional (3D) stacked semiconductor devices. In some examples, a 3D stacked semiconductor device may include an integrated folded data path. Such a folded data path can reduce wire delay by physically locating data sources nearer execution units, thereby reducing a requisite length of the data path.

In at least one example, a semiconductor device can include a first die that can include a data source and a second die that can include an execution unit. The second die can be oriented along a common plane with the first die. Furthermore, the second die can be positioned relative to the first die along a vertical axis, the vertical axis being perpendicular to the common plane. The semiconductor device can also include a data path that electrically couples the data source in the first die and the execution unit in the second die, thereby facilitating communication between the data source and the execution unit.

The design of semiconductor devices has become increasingly important in addressing challenges associated with wire delays and spatial constraints in processor design. The utilization of a 3D stacked configuration in semiconductor devices offers a strategic approach to minimize the distance between critical components, such as data sources and execution units. This approach not only enhances the efficiency of data transfer within the device but also contributes to overall improvements in processor speed and performance. The vertical stacking of components, as opposed to traditional planar layouts, opens new avenues for optimizing the layout of semiconductor devices, enabling the inclusion of more functional units within a confined space without compromising on device performance.

In this context, the folded data path concept as described herein may serve to reduce wire delays by ensuring that the data sources and execution units are located in close proximity within the vertical stack. This proximity is achieved by the strategic orientation and positioning of the dies that house these components. By aligning the second die, which contains the execution unit, along a vertical axis perpendicular to the plane shared with the first die, which contains the data source, variations of the principles described herein can provide a compact yet efficient pathway for data communication. This arrangement not only facilitates quicker data transfers but also contributes to a reduction in routed signal congestion with associated improvements in density and crosstalk interference.

This layered approach allows for a versatile construction of semiconductor devices, accommodating various types of data paths and execution units, including those optimized for specific computational tasks such as floating-point and integer operations. The ability to tailor the data path and components within the silicon stack to specific processing needs offers significant advantages in terms of device customization and targeted performance enhancement. This flexible design paradigm ensures that the semiconductor devices can be adapted to a wide range of applications, from general computing to specialized tasks in data centers and advanced computing systems, thereby addressing the diverse needs of modern technology landscapes.

In certain variations, the semiconductor device may include multiple data sources coupled to a single execution unit, or multiple data sources coupled to multiple execution units. This arrangement allows for increased flexibility and efficiency in data processing by providing multiple sources of data for a single execution operation, or by enabling parallel processing of data from multiple sources. In such configurations, each data source could be located on a separate die or multiple data sources could be located on a single die, and similarly for the execution units.

In one example, a semiconductor device includes a first die and a second die. The first die can include one or more data sources, and the second die can include one or more execution unit. The second die is oriented in a common plane with the first die and positioned relative to the first die in a vertical dimension perpendicular to an orientation of the common plane. The semiconductor device can also include one or more data paths that electrically couples the data source(s) and the execution unit(s).

Another example can be the previously described semiconductor device, wherein (1) the first die, the second die, and the data path are included in a silicon stack including a plurality of layers, (2) the first die is included in a first layer of the silicon stack, (3) the second die is included in a second layer of the silicon stack, and (4) the data path transits the silicon stack between at least the first layer and the second layer.

Another example can be the previously described semiconductor device, wherein the data path transits at least one intermediary layer in the silicon stack, the at least one intermediary layer disposed in the silicon stack between the first die and the second die.

Another example can be the previously described semiconductor device, wherein the at least one intermediary layer includes a bonding layer that affixes at least one of the first layer or the second layer within the silicon stack.

Another example can be any of the previously described semiconductor devices, wherein at least one of (1) the data path is a floating-point data path, (2) the data source is a floating-point data source, or (3) the execution unit is a floating-point execution unit.

Another example can be any of the previously described semiconductor devices, wherein at least one of (1) the data path is an integer data path, (2) the data source is an integer data source, or (3) the execution unit is an integer data source.

Another example can be any of the previously described semiconductor devices, wherein the data source includes an additional execution unit.

Another example can be any of the previously described semiconductor devices, wherein the data source includes at least one of (1) a physical register file, (2) a reservation station, (3) a data cache, (4) an instruction cache, or (5) a data queue.

Another example can be any of the previously described semiconductor devices, wherein the execution unit includes at least one of (1) an arithmetic logic unit, or (2) an address generation unit.

In another example, a processing unit can include (1) a silicon stack including (A) a first die included in a first layer of the silicon stack, the first die including a data source, (B) a second die included in a second layer of the silicon stack, the second die including an execution unit, and (C) a data path that electrically couples the data source and the execution unit.

Another example can be the previously described processing unit, wherein the data path transits at least one intermediary layer in the silicon stack, the at least one intermediary layer disposed in the silicon stack between the first die and the second die.

Another example can be the previously described processing unit, wherein the at least one intermediary layer includes a bonding layer that affixes at least one of the first layer or the second layer within the silicon stack.

Another example can be any of the previously described processing units, wherein at least one of (1) the data path is a floating-point data path, (2) the data source is a floating-point data source, or (3) the execution unit is a floating-point execution unit.

Another example can be any of the previously described processing units, wherein at least one of (1) the data path is an integer data path, (2) the data source is an integer data source, or (3) the execution unit is an integer data source.

Another example can be any of the previously described processing units, wherein the data source includes an additional execution unit.

Another example can be any of the previously described processing units, wherein the data source includes at least one of (1) a physical register file, (2) a reservation station, (3) a data cache, (4)) an instruction cache, or (5) a data queue.

Another example can be any of the previously described processing units, wherein the execution unit includes at least one of (1) an arithmetic logic unit, (2) an address generation unit, (3) a crossbar mux, or (4) a functional unit.

A further example can be a method including (1) providing (A) a first die including a data source, and (B) a second die including an execution unit, (2) orienting the second die in a common plane with the first die, (3) positioning the second die relative to the first die in a vertical dimension perpendicular to an orientation of the common plane such that the data source and the execution unit are substantially aligned with one another in the vertical dimension, and (4) forming a data path that electrically couples the data source and the execution unit.

Another example can include the previously described method, wherein forming the data path that electrically couples the data source and the execution unit includes forming the data path within an intermediary layer that separates the first die and the second die.

Another example can include the previously described method, wherein (1) the first die is included in a first layer of a silicon stack, (2) the second die is included in a second layer of the silicon stack, (3) the silicon stack further includes at least one intermediary layer including a bonding layer that affixes at least one of the first layer or the second layer within the silicon stack, and (4) the method further includes bonding the first layer and the second layer within the silicon stack via the bonding layer.

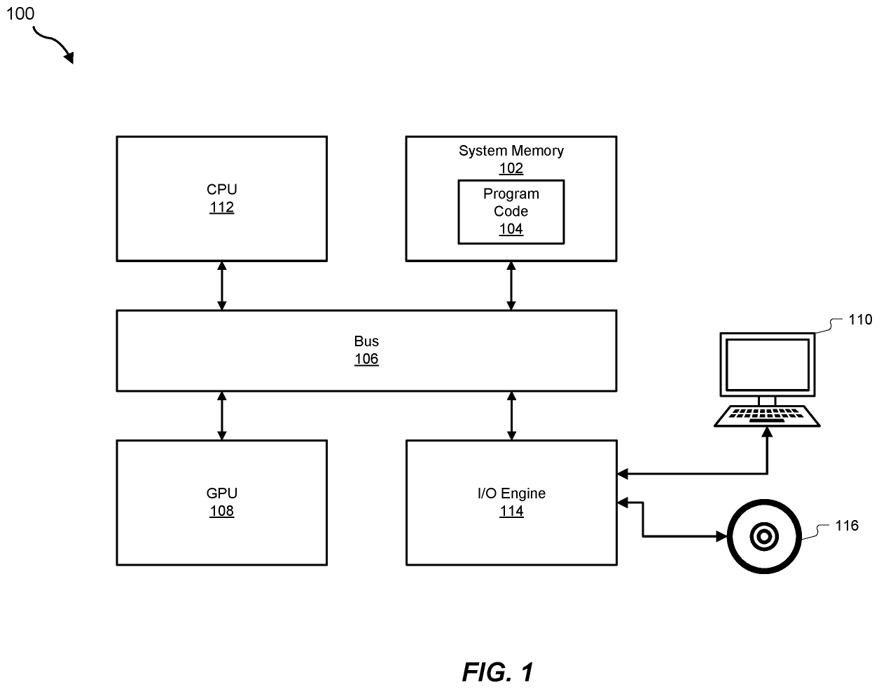

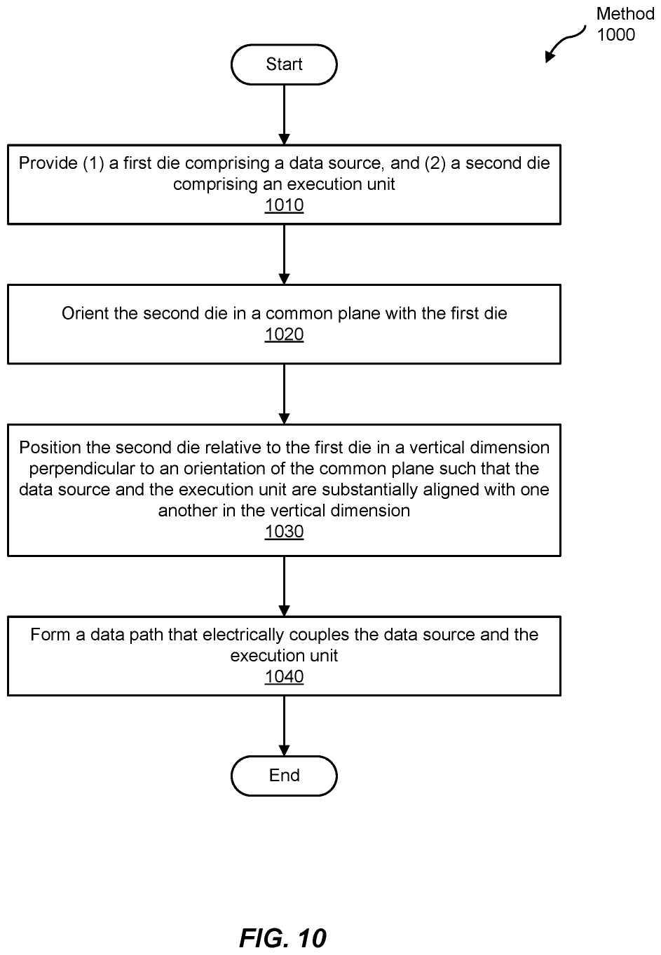

The following will describe, in reference to FIG. 1 through FIG. 9, various devices and systems that can incorporate folded data paths for enhanced wire delay optimization. Additionally, the following will describe, in reference to FIG. 10, various methods of constructing folded data paths for enhanced wire delay optimization.

In some examples, a data source can include any component, system, or arrangement capable of providing, generating, storing, or outputting data for processing or use within a semiconductor device. This includes, but is not limited to, memory units, registers, buffers, caches, input/output interfaces, sensors, converters (such as analog-to-digital or digital-to-analog converters), and any other form of data-generating or data-holding hardware.

By way of illustration, a data source may include a physical register file (PRF), a reservation station (RS), and/or an output of an execution unit. The data source may contain static or dynamic data, and may be configured to provide data in various formats or protocols suitable for processing by an execution unit. It may include integrated circuits, programmable logic devices, or any other form of electronic componentry designed to hold or produce data. The data source may be internal or external to the semiconductor device and may interact with other components of the device through wired or wireless communication means.

In some examples, an execution unit can include any component, module, or subsystem within a semiconductor device that is responsible for executing computational tasks. This can encompass, but is not limited to, units capable of performing arithmetic operations, logic operations, data processing tasks, and/or control operations. Examples of execution units can include, without limitation, arithmetic logic units (ALUs), floating point units (FPUs), graphics processing units (GPUs), address generation units (AGUs), and/or specialized processors such as those used in artificial intelligence and/or machine learning applications.

An execution unit may be designed to handle specific types of data and operations, such as integer or floating-point arithmetic, or it may be adaptable to various data types and/or instructions. An execution unit may operate independently or in conjunction with other execution units within the semiconductor device. An execution unit can also be a part of a larger system, such as a central processing unit (CPU) or a multiprocessor system, and may interact with other components of the device, including memory units, input/output interfaces, and data sources, through various data paths and communication protocols.

In some examples, execution units can be characterized by an ability to receive instructions and data, perform the necessary computations or operations as dictated by the instructions, and output or store the resulting data. The use of the term execution unit herein is intended to be inclusive of current technologies as well as future advancements that may introduce new forms of execution units or new methods of executing computational tasks within semiconductor devices.

In some examples, a data path can include and/or encompass any structure, mechanism, or configuration within a semiconductor device that facilitates the transfer, communication, or routing of data between components. This can include, but is not limited to, electrical connections, conductive traces, buses, wires, and wireless communication channels that enable the movement of data within the device. A data path can serve to connect various elements such as data sources, execution units, memory units, input/output interfaces, and other functional units within the semiconductor device.

In some variations, a data path can be designed to handle various types of data, including but not limited to, digital signals, analog signals, and mixed-signal formats. It can support different data protocols and transmission speeds, and can be optimized for specific types of data processing and computational tasks. A data path can also include additional components such as amplifiers, converters, buffers, multiplexers, and demultiplexers to facilitate and manage the data flow.

Furthermore, a data path can be configured in various architectural designs, including point-to-point connections, bus structures, network configurations, and any other arrangement that enables effective and efficient data transmission within the semiconductor device. The data path can be part of a larger system, encompassing internal and external communication channels, and can interact with external devices and networks. Furthermore, data paths can be integrated within a silicon substrate or as separate interconnects, depending on design choices.

The use of the term data path herein is intended to be inclusive and adaptable to encompass current technologies and future advancements in semiconductor device design and data communication methodologies. The broad scope of this term covers a wide range of configurations and technologies used for data transfer within semiconductor devices.

Likewise, in some examples, a die can encompass any small block or segment of semiconductive material on which a given functional circuit is fabricated. Typically made from a slice or wafer of semiconductor, such as silicon, a die can house integrated circuits and can form a functional unit of a semiconductor device.

A die can include various components and circuits, such as transistors, resistors, capacitors, interconnects, and other microelectronic components, which are used to perform electronic functions. The specific configuration and components of a die can vary widely depending on its intended application, ranging from simple circuits to complex microprocessors, memory chips, and other sophisticated electronic systems.

A die can also encompass advancements in semiconductor technology, including but not limited to multi-layered dies, 3D-stacked dies, and those employing advanced fabrication techniques such as fin field-effect transistors (FinFET), silicon-on-insulator (SOI), gate-all-around (GAA) transistors, and beyond. A die can be a standalone unit or part of an integrated system, such as a system-on-chip (SoC) or a multi-chip module (MCM).

Furthermore, use of the term die herein is intended to be inclusive of future developments in semiconductor materials and fabrication technologies that may introduce new forms of dies or novel methods of integrating circuits and components on a semiconductive material, covering a wide range of existing and potential future semiconductor technologies and configurations.

FIG. 1 depicts a block diagram of a processing system 100, according to some implementations of the present disclosure. The processing system 100 includes or has access to a system memory 102, implemented using a non-transitory computer-readable medium, such as dynamic random-access memory (DRAM). Additionally, the system memory 102 may also be implemented using other types of memory, including static random-access memory (SRAM), nonvolatile RAM (NVRAM), or spin-torque RAM (STRAM). The system memory 102, being external, is implemented outside the processing units of the processing system 100. Contained within the system memory 102 is program code 104, which comprises instructions executable by the processing system 100 to perform various operations. Furthermore, processing system 100 incorporates a bus 106, facilitating communication between components within the system, such as the system memory 102 and the program code 104.

The processing system 100 is also equipped with a graphics processing unit (GPU) 108, designed to render images for display on a display unit 110. The GPU 108 is tasked with rendering graphical objects, producing pixel values supplied to the display unit 110, which then visualizes the images. Beyond image rendering, the GPU 108 is also capable of general-purpose computing, processing instructions from the program code 104 stored in system memory 102 and storing results back into it.

Processing system 100 also includes a central processing unit (CPU) 112, which connects to the rest of the system via bus 106. The CPU 112 interfaces with both the GPU 108 and system memory 102 through the bus 106, executing stored instructions and managing the data processing. It also plays a role in initiating graphics processing, sending commands to GPU 108 as required.

Additionally, the processing system 100 includes an input/output (I/O) engine 114, managing input and output operations related to various system components, including the display unit 110. The I/O engine 114, connected through bus 106, facilitates interaction with other system components, such as system memory 102, GPU 108, and CPU 112. It manages various peripheral and external device communications and can interact with an external storage device 116, which is implemented as a non-transitory computer-readable medium like a compact disk (CD) or a digital video disc (DVD). The I/O engine 114 can both read from and write to the external storage device 116, enabling data storage and retrieval as part of the processing system's operations.

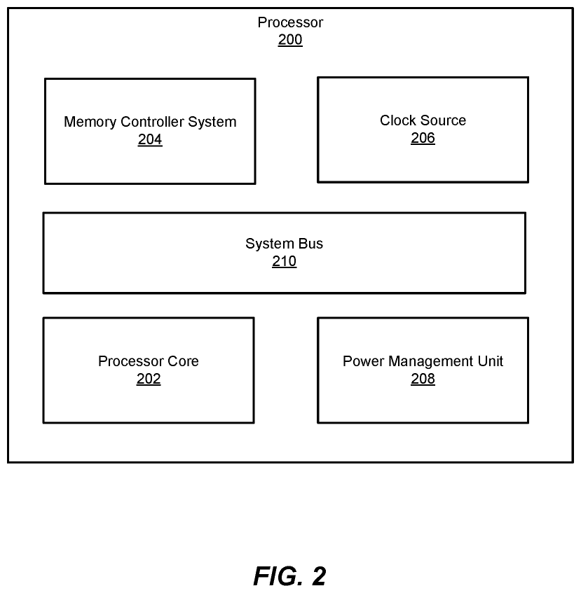

A CPU or GPU (generically, a “processor”) such as GPU 108 and/or CPU 112, may include a number of instances of a core, along with other features. One example of a processor with a single core instance is depicted in FIG. 2. As shown, processor 200 includes one instance of a core, denoted as core 202. Core 202 is coupled to a system bus 210. A memory controller system, labeled as memory controller system 204, is also coupled to system bus 210 and includes off-chip connections to available system memories (e.g., system memory 102). A clock source, denoted as clock source 206, and a power management unit, referred to as PMU 208, are each coupled to core 202.

Core 202 is configured to execute instructions and process data according to a specific Instruction Set Architecture (ISA). In this example, core 202 is designed to implement a particular ISA, although other variations may employ any desired ISA, such as x86, ARM®, PowerPC®, or MIPS®. Furthermore, in this configuration, core 202 is designed to execute multiple threads concurrently, allowing each thread to include a set of instructions that can operate independently from another thread. It is contemplated in various examples that any suitable number of cores may be included within processor 200, and that core 202 may concurrently process a number of threads.

Core 202 may include multiple subsystems for executing various instructions. To support multiple threads, core 202 features additional circuits and buffers for managing each active thread. A sequencing unit in core 202 determines the thread to which each instruction belongs, storing the instruction in the corresponding instruction fetch buffer. In some variations, core 202 may include one or more coprocessors to assist the main execution unit. Examples of suitable coprocessors include floating point units, encryption coprocessors, or digital signal processing engines. Certain subsets of the ISA may be directed towards a coprocessor rather than being executed by the main execution unit.

The memory controller system 204 provides control logic, buffers, and interfaces for accessing memory external to processor 200. The memory controller system 204 may include interfaces for different types of off-chip memory, such as DRAMs, SRAMs, HDDs, SSDs, and more. In various examples, memory controller system 204 may be equipped with circuits for communicating with a variety of memory types.

System bus 210 is configured to manage data flow between core 202 and other components in processor 200, like clock source 206, PMU 208, and others. In one configuration, system bus 210 may include elements such as multiplexers or a switch fabric. Some configurations of system bus 210 may feature logic to queue data requests and responses, preventing requests and responses from hindering other activities while awaiting service. Various types of interconnect networks may be used to implement system bus 210.

Clock source 206 provides clock signals for core 202, offering either consistent or variable frequencies. Clock signal frequencies can be adjusted using local clock divider circuits or by selecting from multiple signals via switches or multiplexors.

PMU 208 controls the distribution of power supply signals within processor 200, adjusting voltage levels to core 202. Voltage levels can be modulated using voltage regulating circuits or selecting from multiple power supply signals. Commands to adjust voltage levels may originate from other components within processor 200, such as core 202 or temperature sensing units.

FIG. 2 illustrates just one configuration of a processor. Other examples of processor 200 might include additional features such as cache memory or network interfaces. While FIG. 2 suggests a logical organization of circuits, physical arrangements may vary, and other components might be included in different configurations of processor 200.

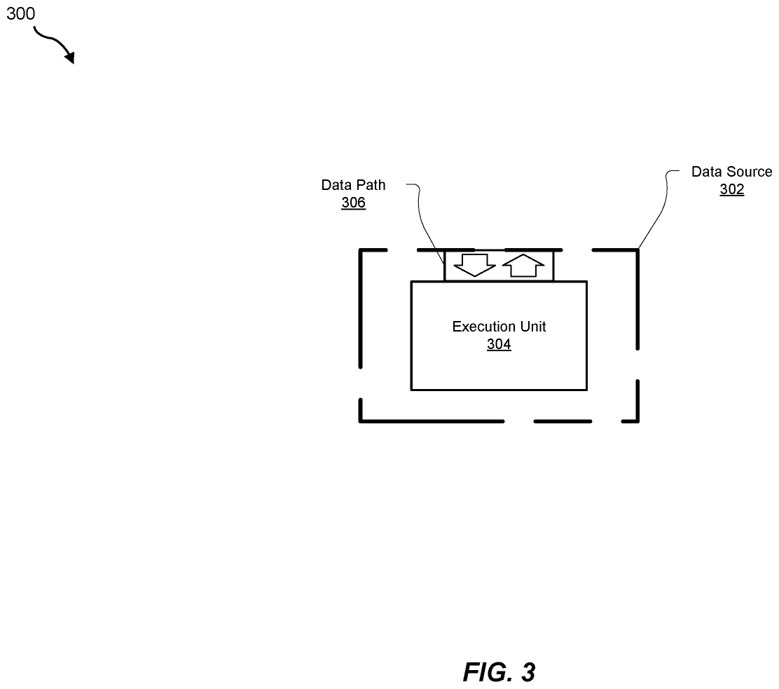

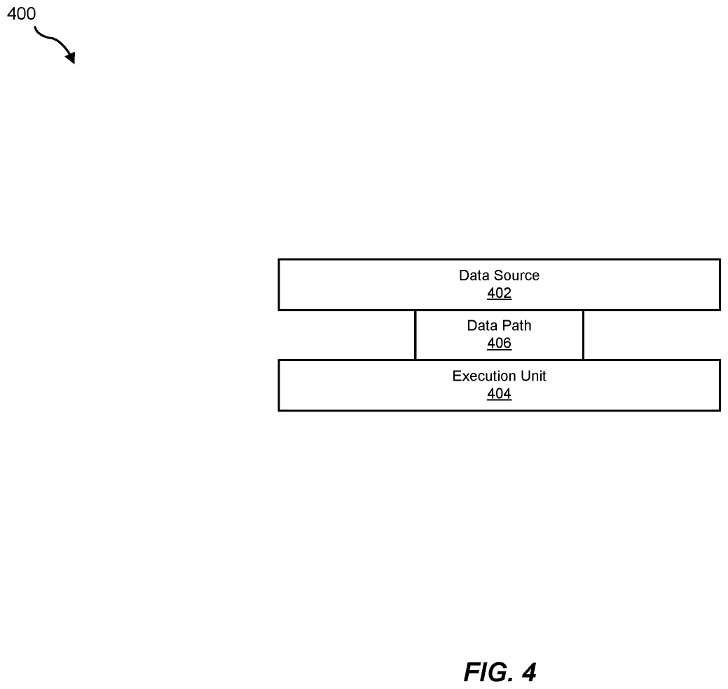

A processor core, such as core 202 and/or CPU 112, may include at least one data source and at least one execution unit, with at least one data path that electrically and/or communicatively couples the data source to the execution unit. FIG. 3 and FIG. 4 provide block diagrams of example processor cores, illustrating how these components are integrated and interact within the core.

FIG. 3 presents a top view 300 of an example processor core that includes a data source 302, an execution unit 304, and a data path 306. Data source 302, represented with dashed and dotted lines, is positioned relative to execution unit 304 to optimize data communication efficiency. The illustrative convention of dashed and dotted lines for data source 302 serves to indicate its placement at a different layer or elevation within the core, such as an upper layer, that if depicted in solid lines might obscure underlying components like execution unit 304 and data path 306.

Execution unit 304 occupies a central location that enables optimized data receipt and processing. Data path 306 is depicted as a line or channel, signifying its role in the bidirectional flow of data. It acts as a critical link that ensures the execution unit 304 has timely and reliable access to the data provided by data source 302, facilitating seamless communication within the processor core. The design of data path 306 is such that it can support rapid data transfer rates and low-latency operations, which can satisfy the core's high-speed computational demands.

FIG. 4 shows a cross-section view 400 of a portion of an example processor core that can include a data source 402, an execution unit 404, and a data path 406. As illustrated in this figure, data source 402 is situated above the execution unit 404 and is directly connected to it via data path 406. This arrangement signifies a vertically integrated structure within the processor core, optimizing the internal layout for efficient data transfer and processing. The data source 402 is configured to supply or store data necessary for the execution of instructions, while the execution unit 404 is tailored to carry out the computational tasks required by the processor core. The data path 406, represented as a line or linkage, facilitates the movement of data between the data source and the execution unit. This streamlined configuration demonstrates the compact and interconnected nature of the components within the processor core, suggesting a design that is both space-efficient and conducive to high-speed data handling.

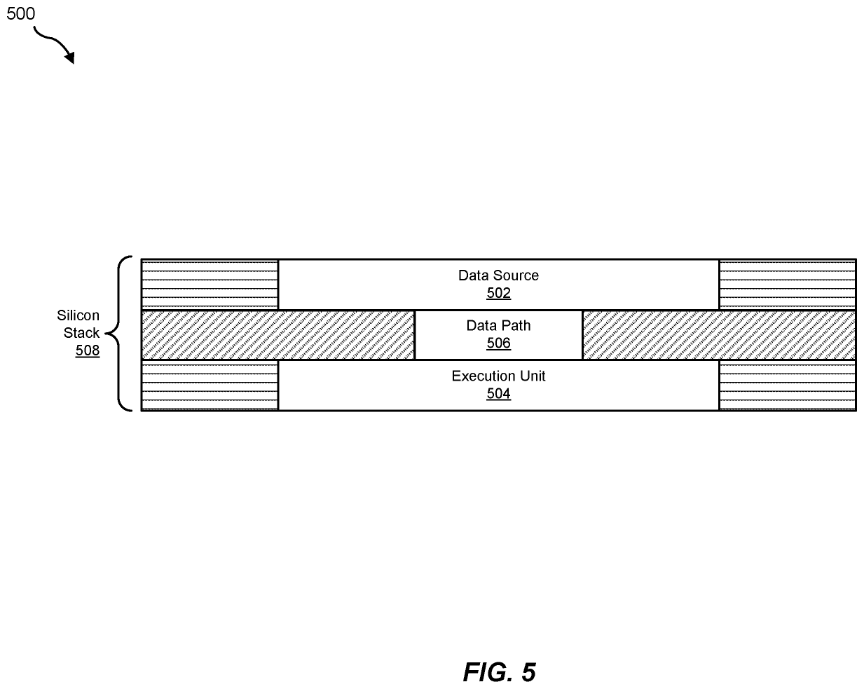

As described above, a data source, an execution unit, and a data path as described herein can be incorporated into and/or included as part of a silicon stack. FIG. 5 shows a cross-section view 500 of a data source 502, execution unit 504, and data path 506 included on different layers or dies within a silicon stack 508. In this configuration, data source 502 is situated on a first, upper layer, while execution unit 504 is placed on a second, lower layer, highlighting a vertical integration strategy that utilizes the z-axis for component placement to enhance data communication efficiency. Data path 506 is interposed between the data source 502 and execution unit 504. Data path 506 can serve as a conduit for electrical signals and information transfer between data source 502 and execution unit 504 across and/or between layers of a silicon stack. Silicon stack 508 represents the collective structure of these layers, showcasing the compact and efficient design enabled by 3D integration technology. Although depicted as a distinct layer within silicon stack 508 and/or as a via that transits a distinct intermediary layer disposed between a first layer and a second layer within the silicon stack, this is by way of illustration only, and in some variations, data path 506 may not be included as a separate layer in a silicon stack (e.g., silicon stack 508), but may couple data source 502 and execution unit 504 across a gap between layers that those components occupy. In additional or alternative examples, the intermediary layer may include a bonding layer that affixes the first layer and/or the second layer within the silicon stack.

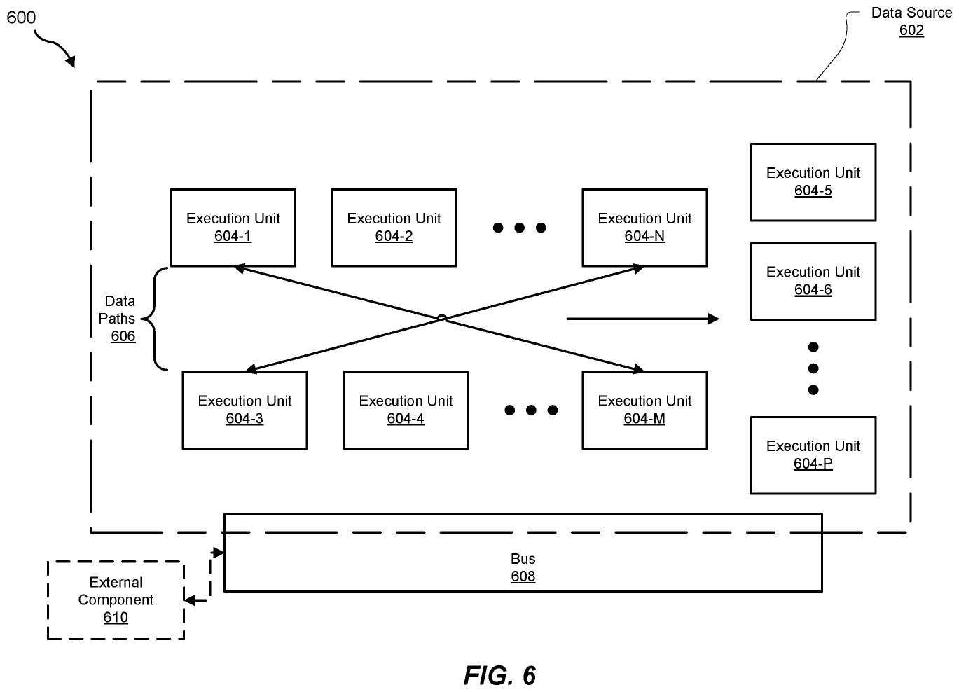

In some implementations, a processor core may include a plurality of data sources, a plurality of execution units, and/or a plurality of data paths. FIG. 6 shows a top view 600 of an example implementation of a processor core that includes a data source 602, a plurality of execution units 604 (e.g., execution unit 604-1 through execution unit 604-N, execution unit 604-3 through execution unit 604-M, and execution unit 604-5 through 604-P).

Note that the number and configuration of data sources, execution units, and/or data paths is provided by way of example only and not intended to limit the scope of this disclosure. In some embodiments, the second die of the semiconductor device may include a plurality of execution units. These execution units may take the form of various types of processing devices, such as arithmetic logic units, address generation units, crossbar mux, or functional units, which may work individually or in conjunction to process data from the data source(s). In other embodiments, the first die of the semiconductor device may include a plurality of data sources. These data sources may include components such as physical register files, reservation stations, data caches, instruction caches, or data queues, and so forth.

In these configurations, the semiconductor device may further include a plurality of data paths. Each of these data paths electrically couples a corresponding one of the plurality of data sources in the first die to an execution unit in the second die. This arrangement allows for efficient data transfer and processing, as each data source may be coupled to a dedicated execution unit.

In yet other embodiments, the first die may include a plurality of data sources and the second die may include a plurality of execution units. In this case, a plurality of data paths may electrically couple each data source to multiple execution units in the second die. This configuration allows for increased processing power and flexibility, as each data source may supply data to multiple execution units, and each execution unit may process data from multiple data sources.

These configurations provide a high degree of flexibility and customization in the design of the semiconductor device. By altering the number and types of data sources and execution units, and the configuration of the data paths between them, the device may be tailored to meet the specific processing requirements of a given application.

Moreover, the positioning of the data source relative to the execution units may vary based on the specific architecture and design goals of the semiconductor device. In some implementations, the data source may be centrally located relative to the execution units, facilitating equal or near-equal path lengths to each execution unit. This may minimize latency variations and ensure balanced data flow. In other implementations, the data source may be off-center, closer to certain execution units that are more frequently used or require faster data access.

As depicted in FIG. 6, the processor core is arranged such that data source 602 is capable of interfacing with multiple execution units. The illustration shows a network of data paths 606, represented as lines that connect data source 602 to each of the execution units 604. As with other examples illustrated herein, the position of the data source 602 relative to the execution units 604 can be centrally located, off-center, or any other configuration depending on the specific needs of the processor core design. Data paths 606 are designed to facilitate parallel and/or selective data transmission, allowing data source 602 to communicate simultaneously or individually with one or more of the execution units, depending on the processing requirements. Likewise, each execution unit may communicate with any other execution unit to facilitate efficient process operations.

The array of execution units is connected via a bus 608, which provides a common communication channel for the interchange of data, control signals, and synchronization between the execution units and other components of the processor core, enabling a harmonized and coordinated data flow within the processor core.

An optional external component 610, depicted by dashed lines, is also connected to the bus 608. This component, which could represent a variety of external devices or systems, is configured to interact with the semiconductor device by either transmitting data to or receiving data from the semiconductor device. This interaction allows for enhanced functionality and versatility in the system's operations.

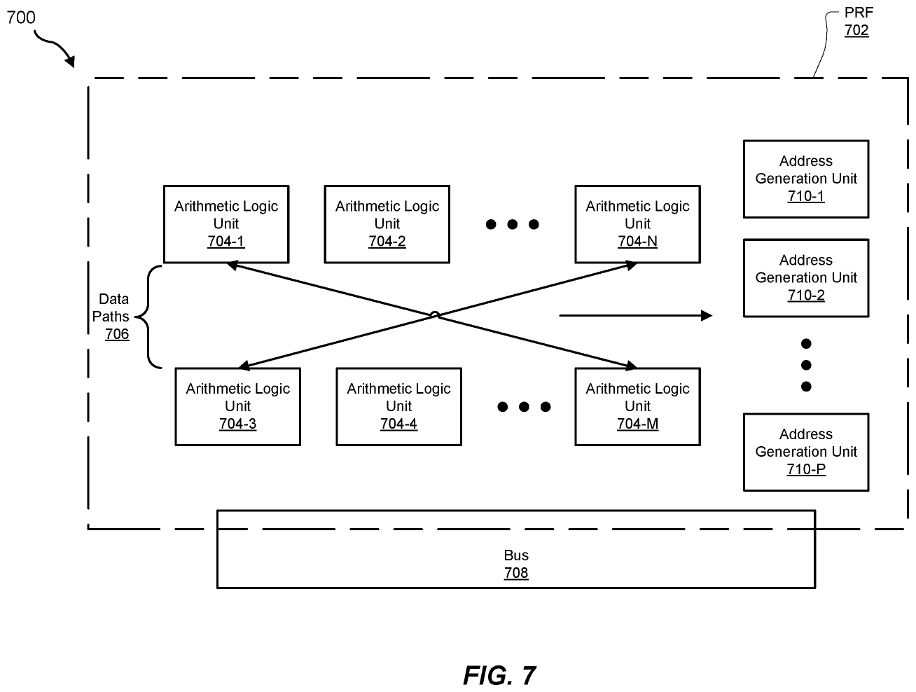

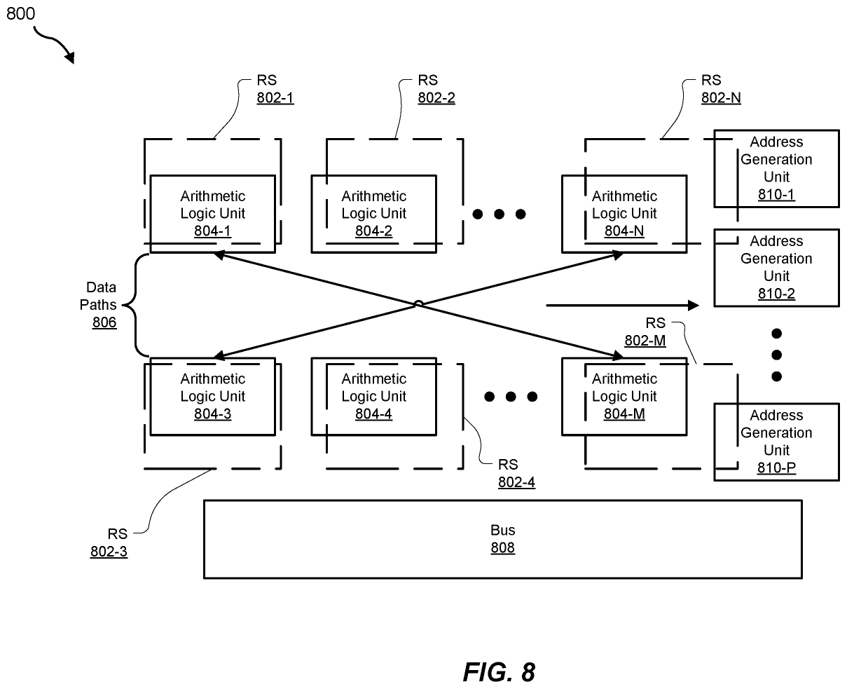

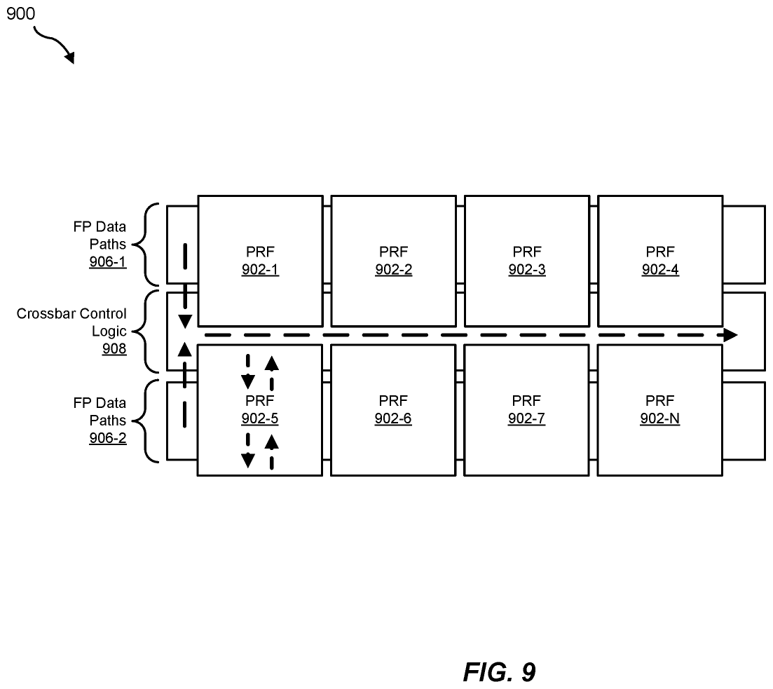

As will be described in greater detail below in reference to FIG. 7, the execution units themselves may be specialized to perform various computational tasks. For example, some execution units could be optimized for arithmetic calculations, while others may handle vector processing or complex logical operations. The diverse functionalities of these execution units, coupled with the flexible data routing provided by data paths 606, allow for a highly adaptable processor architecture capable of executing a wide range of instructions in parallel or in a pipelined fashion.

It is also contemplated that data source 602 and execution units 604 could be integrated into a single die or distributed across multiple dies within a semiconductor device. Furthermore, the data paths 606 could be implemented using various technologies such as metallic interconnects, optical links, or wireless communication protocols, providing a versatile approach to data transmission within the processor core.

While FIG. 6 presents one example configuration of a processor core, it should be understood that the scope of the disclosure is not limited to the specific arrangement shown. Various modifications and additions can be made to tailor the processor core's design to suit different performance criteria, power efficiency goals, and application-specific requirements. The depiction of the processor core in FIG. 6 illustrates a scalable and modular approach to processor design, reflecting the broad potential for customization inherent in modern semiconductor architectures.

FIG. 7 and FIG. 8 show different possible configurations of data sources and execution units, with FIG. 7 showing an implementation that incorporates a PRF as a data source and FIG. 8 showing an implementation that incorporates a plurality of RSs as data sources. PRFs and RSs are both useful components in processor architecture, but they can serve different purposes. PRFs are storage areas within a processor that hold data values that the processor may use in execution. Comprised of a collection of registers, each capable of holding a word of data, a PRF provides rapid access to operands for the processor's arithmetic and logic operations. These registers can be read or written by the execution units and are a limited resource within the processor. PRFs are often the final destination for the results of completed instructions and the initial source for operands when instructions are issued. They are organized to allow for fast access to frequently used data, enabling quick read and write operations by the execution units.

RSs, on the other hand, act as a staging area for instructions that are ready to be executed but are waiting for their operands to become available. They temporarily hold the instructions, along with the operands or pointers to the operands, and control information until the execution units are ready to process them. This system allows for out-of-order execution, where instructions can be processed as soon as their data dependencies are resolved, rather than strictly in the order they appear in the program.

One difference between PRFs and RSs lies in their roles in instruction execution. PRFs are focused on data storage and accessibility, directly impacting the speed of data retrieval and execution in the processor's pipeline, while RSs are more about instruction management and readiness, contributing to the efficiency of instruction throughput. Both PRFs and RSs are helpful for the efficient operation of a modern processor, facilitating a high level of parallelism and rapid execution of complex instruction sets.

FIG. 7 shows a top view 700 of an example implementation of a processor core where the data source is a PRF 702 and the execution units include a number of ALUs 704 (e.g., ALU 704-1 through ALU 704-N and ALU 704-3 through ALU 704-M) and a number of AGUs 710 (e.g., AGU 710-1 through AGU 710-P). As shown, this configuration further includes a bus 708 that, like bus 608 in FIG. 6, provides a common communication channel for the interchange of data, control signals, and synchronization between the execution units and other components of the processor core.

As execution units, each ALU 704 within the processor core is configured to perform a variety of arithmetic and logical operations, which are fundamental to the processor's function. The multiple ALUs enable parallel processing and efficient execution of multiple instructions. Similarly, the AGUs 710 are specialized for calculating addresses used by the processor core for accessing data in memory, which is critical for operations like load and store instructions. The plurality of AGUs allows for concurrent address generation, enhancing the core's ability to manage complex data structures and memory-intensive tasks.

As with data paths 606 above in FIG. 6, the data paths 706, illustrated as connections between the PRF 702, ALUs 704, and AGUs 710, facilitate the movement of data within the processor core. They enable the dynamic routing of operands and results to and from the PRF 702 and between the various execution units, thereby optimizing the core's data handling capabilities. The data paths 706 are designed to minimize latency and maximize throughput, ensuring that the execution units operate at peak efficiency.

Bus 708 enables communication across the core's various components. It allows for the unified management of data transactions, control flow, and synchronization signals, which is essential for maintaining the operational integrity of the processor core. The bus architecture may incorporate advanced features such as arbitration, queuing, and prioritization mechanisms to handle the communication demands of the processor core effectively.

While FIG. 7 presents a specific arrangement of PRF 702, ALUs 704, AGUS 710, and bus 708, it is to be understood that the depiction is not limiting. The processor core may be adapted to include additional or fewer ALUs and AGUs, different types of execution units, or alternative data source configurations. This illustration exemplifies the modular nature of processor core design, allowing for scalable and adaptable architectures that can be customized to meet various processing needs and objectives.

Turning to FIG. 8, FIG. 8 shows a top view 800 of an example implementation of a processor core where the data source is a plurality of RSs and, like in FIG. 7, the execution units include a number of ALUs 704 (e.g., ALU 804-1 through ALU 804-N and ALU 804-3 through 804-M) and a number of AGUs 810 (e.g., AGU 810-1 through AGU 810-P). As in FIG. 7, this implementation includes a bus 808 that provides a common communication channel for the interchange of data, control signals, and synchronization between the execution units and other components of the processor core.

Each RS 802 in the processor core can serve as a temporary holding area where instructions wait until the necessary operands are available to execute them, effectively managing the flow of operations to the execution units. The RSs are depicted as various blocks, indicating that they may hold different types of instructions or data specific to the operation of the associated ALUs and AGUs.

As with ALUs 704 and AGUs 710 above, the ALUs 804 are tasked with performing the processor core's arithmetic and logical functions, while the AGUs 810 handle the address computations for memory access operations, vital for tasks such as fetching data from or storing data to memory. The data paths 806, shown as lines connecting RSs to ALUs and AGUs, represent the routes along which operands, instructions, and address information are transmitted within the processor core.

The bus 808, similar to bus 708 in FIG. 7, enables integrated and efficient communication across the processor core. It serves as the central conduit through which the RSs, ALUs, AGUs, and other processor components send and receive data and control signals. This organization ensures that instructions and data can be dynamically routed to the appropriate execution units as needed for efficient processing.

While FIG. 8 presents one example configuration with a specific number and arrangement of RSs, ALUs, and AGUs, it is emphasized that the depiction is illustrative and not exhaustive. The processor core may be configured with varying numbers of these components and in different arrangements to meet particular processing demands or performance specifications.

While some of the foregoing examples have been focused on integer operations, the systems and methods disclosed herein can also be applied to floating-point operations. In a processor, integer operations involve arithmetic and logical tasks on whole numbers and are managed by integer execution units. These units interact with integer-specific data sources like integer registers, utilizing optimized data paths designed for swift integer data handling. Floating point operations, however, handle real numbers with fractional parts, requiring floating point execution units that can process a wider and more complex range of values. Floating point registers in the data sources accommodate the increased data size and precision, and the corresponding data paths are tailored to manage the intricate data flow. The key distinction lies in the data complexity and the specialized execution units and data paths required for each operation type, with floating point computations typically demanding more processing power and time than integer calculations.

FIG. 9 shows a top view 900 of an example implementation of a processor core where the data source, execution unit, and data path support floating point operations. In this example, a data source includes a plurality of PRFs 902 (e.g., PRF 902-1 through 902-N), a plurality of data paths 906 (e.g., data path 906-1 and data path 906-2) and crossbar control logic 908. While not shown in FIG. 9, crossbar control logic 908 may transmit data between PRFs 902, data paths 906, and one or more execution units.

In some examples, crossbar control logic 908 can refer to a specialized hardware mechanism that manages the routing of data between multiple sources and destinations within a processor, effectively functioning as a switchboard. When dealing with floating point operations, which are complex and can involve numerous data sources and execution units, the crossbar control logic can ensure that the correct data reaches the appropriate execution unit at the right time.

The crossbar control logic dynamically connects multiple floating-point registers (e.g., one or more of PRFs 902) to floating point execution units through various data paths 906. Crossbar control logic 908 can accommodate simultaneous data transfers, allowing for parallel processing and efficient utilization of the execution units. This can be particularly important for floating point operations that require significant computational resources and can benefit from parallelism to improve performance. In essence, crossbar control logic 908 can represent a sophisticated form of data traffic management that allows for high-speed, concurrent access to execution units by multiple data sources, optimizing the flow of floating-point operations.

In FIG. 9, the arrows are indicative of dynamic routing capabilities provided by crossbar control logic 908 within the processor architecture. The diagram illustrates how floating-point data can be transferred through data paths 906-1 and 906-2, which interconnect a series of PRFs 902-1 through 902-N with various execution units (not explicitly shown in FIG. 9). The arrows signify the bidirectional flow of data, enabling each PRF to either supply data to or receive data from the execution units. This configuration highlights the flexible nature of the crossbar control logic 908, which is designed to selectively establish connections between any given PRF, and an appropriate execution unit as required by computational processes. The arrows thus exemplify the many-to-many connectivity and the versatile data transfer mechanisms that are integral to the efficient operation and high throughput capabilities of the processor's floating-point operations.

Continuing to FIG. 10, FIG. 10 includes a flow diagram of an example method 1000 for manufacturing a semiconductor device in accordance with the principles described herein. As shown, step 1010 involves providing a first die that includes a data source and a second die that comprises an execution unit. The first die can serve as a foundation for subsequent layering, housing the data source which may include elements such as registers or memory cells designed to store and provide data. The second die, containing the execution unit, is purposed for processing this data, capable of performing a variety of computational operations.

At step 1020, a suitable instrumentality can orient the second die in a common plane with the first die, ensuring that both dies lie flat relative to one another, facilitating a coherent and streamlined manufacturing process. Subsequently, step 1030 details positioning the second die relative to the first die in a vertical dimension perpendicular to the orientation of the common plane. This positioning can be important as it can include substantially aligning the data source and the execution unit in the vertical dimension, optimizing the path for data flow and potentially minimizing latency and physical space requirements.

Step 1040 involves the formation of a data path that electrically couples the data source and the execution unit. This path can be used to transmit electrical signals between the data source and the execution unit, enabling the integrated circuit to function as designed. In some examples, the data path is formed within an intermediary layer that separates the first and second dies. This intermediary layer acts as a conduit for electrical connectivity and may also provide structural stability to the overall silicon stack.

As noted above in reference to FIG. 4 and FIG. 5, in some examples, the first die is included in a first layer of a silicon stack, while the second die is included in a second layer of the same stack. Additionally, the silicon stack can incorporate at least one intermediary layer, potentially including a bonding layer. This bonding layer's function is to affix one or both of the first and second layers within the silicon stack. Hence, in some examples, the method shown in FIG. 10 can further include a bonding step, ensuring the secure attachment of the layers, thus finalizing the structural aspect of the semiconductor device.

The steps illustrated in FIG. 10 and described herein depicts a methodical approach to constructing a semiconductor device with a three-dimensional integrated circuit architecture, utilizing vertical stacking to achieve enhanced data communication efficiency and device compactness.

As may be clear from the forgoing, the apparatuses, systems, and methods related to a folded 3D stacked semiconductor device with integrated folded data path as described herein may offer many benefits over traditional processor configurations. Implementations of the apparatuses, systems, and methods described herein can significantly enhance the efficiency and performance of integrated circuits. As described herein, implementations may implement a novel structure that utilizes vertical die stacking to achieve a compact form factor while minimizing wire delay-a critical parameter in high-speed data processing. By vertically aligning a data source and an execution unit across multiple layers, or dies, within a silicon stack, the implementations may reduce the physical distance that signals must travel, thereby accelerating data communication and reducing latency.

In essence, the apparatuses, systems, and methods described herein represent a significant step forward in semiconductor device technology. Variations of the disclosed may offer a holistic solution to the challenges of space constraints and signal delay in complex integrated circuits, providing a path toward faster, more efficient, and more performant electronic systems. The strategic combination of 3D stacking, innovative data path integration, and advanced control logic culminates in a semiconductor device that stands poised to meet the evolving demands of modern technology.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a product in a variety of forms, regardless of the particular type of processor or computer-readable media used to actually conduct the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device comprising:
a first die comprising a data source;
a second die comprising an execution unit, wherein the second die is oriented in a common plane with the first die and positioned relative to the first die in a vertical dimension perpendicular to an orientation of the common plane; and
a data path that electrically couples the data source and the execution unit.

2. The semiconductor device of claim 1, wherein:
the first die, the second die, and the data path are included in a silicon stack comprising a plurality of layers;
the first die is included in a first layer of the silicon stack;
the second die is included in a second layer of the silicon stack; and
the data path transits the silicon stack between at least the first layer and the second layer.

3. The semiconductor device of claim 2, wherein the data path transits at least one intermediary layer in the silicon stack, the at least one intermediary layer disposed in the silicon stack between the first die and the second die.

4. The semiconductor device of claim 3, wherein the at least one intermediary layer comprises a bonding layer that affixes at least one of the first layer or the second layer within the silicon stack.

5. The semiconductor device of claim 1, wherein at least one of:
the data path is a floating-point data path;
the data source is a floating-point data source; or
the execution unit is a floating-point execution unit.

6. The semiconductor device of claim 1, wherein at least one of:
the data path is an integer data path;
the data source is an integer data source; or
the execution unit is an integer data source.

7. The semiconductor device of claim 1, wherein the data source comprises an additional execution unit.

8. The semiconductor device of claim 1, wherein the data source comprises at least one of:
a physical register file;
a reservation station;
a data cache;
an instruction cache; or
a data queue.

9. The semiconductor device of claim 1, wherein the execution unit comprises at least one of:
an arithmetic logic unit;
an address generation unit;
a crossbar mux; or
a functional unit.

10. The semiconductor device of claim 1, wherein the second die comprises a plurality of execution units.

11. The semiconductor device of claim 10, wherein the plurality of execution units comprises execution units of different types.

12. The semiconductor device of claim 1, wherein:
the first die comprises a plurality of data sources; and
the semiconductor device further comprises a plurality of data paths that each electrically couple a corresponding one of the plurality of data sources to the execution unit in the second die.

13. The semiconductor device of claim 1, wherein:
the first die comprises a plurality of data sources;
the second die comprises a plurality of execution units; and
a plurality of data paths electrically couple each data source to multiple execution units in the plurality of execution units.

14. A system comprising:
a semiconductor device comprising:
a first die comprising a data source;
a second die comprising an execution unit, wherein the second die is oriented in a common plane with the first die and positioned relative to the first die in a vertical dimension perpendicular to an orientation of the common plane; and a data path that electrically couples the data source and the execution unit; and
a component external to the semiconductor device configured to interact with the semiconductor device, wherein the interaction comprises at least one of:
transmitting data to the semiconductor device; or
receiving data from the semiconductor device.

15. The system of claim 14, wherein the data source comprises an additional execution unit.

16. The system of claim 14, wherein the data source comprises at least one of:
a physical register file;
a reservation station;
a data cache;
an instruction cache; or
a data queue.

17. The system of claim 14, wherein the execution unit comprises at least one of:
an arithmetic logic unit;
an address generation unit;
a crossbar mux; or
a functional unit.

18. A method comprising:
providing:
a first die comprising a data source; and
a second die comprising an execution unit;
orienting the second die in a common plane with the first die;
positioning the second die relative to the first die in a vertical dimension perpendicular to an orientation of the common plane such that the data source and the execution unit are substantially aligned with one another in the vertical dimension; and
forming a data path that electrically couples the data source and the execution unit.

19. The method of claim 18, wherein forming the data path that electrically couples the data source and the execution unit comprises forming the data path within an intermediary layer that separates the first die and the second die.

20. The method of claim 19, wherein:
the first die is included in a first layer of a silicon stack;
the second die is included in a second layer of the silicon stack;
the silicon stack further comprises at least one intermediary layer comprising a bonding layer that affixes at least one of the first layer or the second layer within the silicon stack; and
the method further comprises bonding the first layer and the second layer within the silicon stack via the bonding layer.
